(19) United States
(12) Patent Application Publication
(10) Pub. No.: US 2006/0115741 A1
(43) Pub. Date: Jun. 1, 2006

(54) Pellicle with small gas generation amount

(75) Inventors: Takashi Kozeki, Yamaguchi (JP); Hiroaki Nakagawa, Yamaguchi (JP)

Correspondence Address: AMIN & TUROCY, LLP, 1900 EAST 9TH STREET, NATIONAL CITY CENTER, 24TH FLOOR,, CLEVELAND, OH, 44114, US

(73) Assignee: Mitsui Chemical, Inc., Tokyo (JP)

(21) Appl. No.: 10/534,554

(22) PCT Filed: Nov. 13, 2003
(86) PCT No.: PCT/JP03/14413

§ 371 Date: May 10, 2005

(30) Foreign Application Priority Data
Nov. 15, 2002 (JP) 2002-332933

(51) Int. Cl. G03F 1/00

(52) U.S. Cl. 430/5

(57) ABSTRACT

A pellicle which can prevent the formation of foreign-matter deposits on a photo-mask during laser beam irradiation or storage and keep a high pattern accuracy for an extended period of time even when an exposure is made using a KrF or ArF excimer laser beam by removing deposit-causing materials from the pellicle itself in advance. During a pellicle producing process, a component member used or a completed product is heated or placed under pressure to thereby remove in advance substances produced from the component member used or the completed product.

### TECHNICAL FIELD

The present invention relates to a pellicle for use in protecting a photo-mask in a step of photolithography for patterning a semiconductor device such as IC, LSI and the like, a liquid crystal display device or the like.

### BACKGROUND ART

In the step of photolithography, the operation is carried out to transfer by exposure of a circuit pattern onto a silicon wafer coated with a resist by using a photo-mask or a photo-mask having the circuit pattern on the surface of a glass plate. In this step, when the exposure is conducted in a state that foreign matter such as dust and the like is adhered to the circuit pattern on the photo-mask, the above foreign matter is also transferred onto the wafer, resulting in the formation of a wafer which is a defective product. In particular, when the exposure is affected by using a stepper, it is highly probable that all chips formed on the wafer may become defective. Therefore, adhesion of foreign matter to the circuit pattern of the photo-mask was a serious problem.

In order to solve this problem, a pellicle has been mounted on a photo-mask and an exposure has been conducted through the pellicle. When this method is used, the infiltration of foreign matter onto the circuit pattern of the photo-mask can be prevented. Even when foreign matter is adhered to a pellicle film in some cases, the foreign matter is not transferred onto a wafer; therefore, the yield of production in manufacturing a semiconductor device or the like is improved.

However, when an exposure has been conducted for an extended period of time with a pellicle as attached and when a light source of g-line of 436 nanometers or i-line of 365 nanometers has been used for the exposure, no foreign matter has been generated on the photo-mask. However, as a short wavelength of a light source of the exposure such as KrF or ArF (248 nanometers for an exposure with a KrF laser and 193 nanometers for an exposure with an ArF laser) has been used for fine circuit line width, the formation of deposits has been confirmed within a pellicle-photo-mask space or on the photo-mask pattern. It has been considered as such because a sulfuric acid used for washing the photo-mask remained on the surface of the photo-mask and this sulfuric acid was reacted with ammonia present in air or in a pellicle member, resulting in becoming foreign matter for forming deposits on the photo-mask. Moreover, this deposition reaction has been promoted as the wavelength of a light source of an exposure becomes short so that a measure to remove the ammonia from the material used for the pellicle has been adopted. Furthermore, by performing such measures as to reduce the concentration of residual sulfuric acid on the photo-mask as much as possible and reduce a sulfurous acid gas generated from a case, deposition of mainly an inorganic material such as ammonium sulfate, ammonium chloride and the like could be effectively suppressed.

Also, at the same time with this, a measure for an organic substance has been sought. Deposition of the substance on the photo-mask was prevented by selecting a material in advance which did not contain a substance having a sublimation property such as 2,6-di-t-butyl-4-methylphenol, naphthalene, 2,6-di-t-butylphenol, 2,4-di-t-butylphenol, benzoic acid and the like (JP1988-64048A).

However, in recent years, there has occurred a problem that foreign matter has been generated during or after an exposure even in combination of a pellicle and a photo-mask in which any of the above measures has been taken.

A problem of these substances could not be solved by measures for preventing the formation of foreign matters, i.e. removing foreign matters from a material in use. To this effect, it has been conventionally carried out to reduce the concentration of residual sulfuric acid, reduce an inorganic compound by preventing the formation of a sulfurous acid gas, or to use a material that does not contain an organic compound having a sublimation property.

An object of the present invention is to provide a pellicle and a method of manufacturing the pellicle which can dispense with the formation of foreign-matter deposits on a photo-mask during laser beam irradiation and storage (to put a pellicle into a case for storage until the next use in a state that a pellicle is attached to a photo-mask), and keep a high pattern accuracy for an extended period of time even when an exposure is made using a KrF or ArF excimer laser beam by removing deposit-causing substances from the pellicle itself in advance.

An object of the present invention is to provide a pellicle and a method of manufacturing the pellicle which can dispense with the formation of foreign-matter deposits on a photo-mask during laser beam irradiation and storage, and keep a high pattern accuracy for an extended period of time even when an exposure is made using a KrF or ArF excimer laser beam by removing deposit-causing substances from the pellicle itself in advance.

### DISCLOSURE OF THE INVENTION

In order to achieve the above object, as a result of an analysis of foreign matters in question, the present inventors have found that foreign matter is unexpectedly a volatile organic compound comprising an ester group, an aliphatic group, a hydrocarbon group and the like. Thus, the present invention has been completed. The organic compound confirmed as a source of foreign matter has not been conventionally specified as a source of foreign matter.

The present invention provides a pellicle, wherein the total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under a nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed.

Furthermore, the invention provides a method of manufacturing a pellicle in which the total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under a nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed,

wherein a step of removing the volatile organic compound from the pellicle is carried out.

Herein, one of the preferred embodiments is that a step of removing a volatile organic compound from a member used for manufacturing a pellicle is carried out.

Further, the present invention provides a pellicle-fed photo-mask with a pellicle being mounted thereon in which the total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under a nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed.

Further, the present invention provides a method of manufacturing a semiconductor device using a photo-mask in a state that a pellicle is mounted thereon in which the total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under a nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed.

The present invention provides a method of using a pellicle in which the total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under a nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed,

wherein the pellicle is used for preventing dust in a process of manufacturing a semiconductor device.

### BEST MODE FOR CARRYING OUT THE INVENTION

[Pellicle]

A pellicle of the present invention is such that a pellicle film is stretched, via an adhesive, on one side of a pellicle frame comprising a metal such as aluminum or the like and the other side of the frame is coated with an adhesive so as to be fixed on a photo-mask. Any known pellicle is used for the pellicle of the present invention. The inside of the pellicle frame is coated with an adhesive which can fix any known foreign matter in some cases. Further, a liner is attached to the surface coated with the adhesive until the pellicle is used since it is manufactured.

[Method of Manufacturing a Pellicle]

In order to provide a pellicle which can prevent the formation of foreign-matter deposits on a photo-mask during laser beam irradiation and storage, and keep a high pattern accuracy for an extended period of time even when an exposure is made using a KrF or ArF excimer laser beam, a pellicle may be manufactured by using a member in which a volatile organic compound generated from the pellicle is removed in advance or a pellicle may be manufactured by removing a volatile organic compound component after the pellicle is assembled.

For example, in manufacturing a pellicle, in order to remove foreign matter on the inside of a frame, a material called an inner wall coating agent is used for coating. Then, in order to tightly adhere it to the photo-mask, the bottom of the frame is coated with a photo-mask adhesive and a liner is attached. After that, the top of the pellicle frame is coated with an adhesive for attaching a film and the film is attached thereon, which is usually encased into a case for storing pellicles. In a series of these manufacturing steps, the removal of the volatile organic compound component may be conducted for each member in a step before a pellicle is manufactured or may also be conducted for each pellicle and case after a pellicle is manufactured.

[Organic Compound to be Collected]

A volatile organic compound component contained in a pellicle in the present invention may be contained in a very small amount in a photo-mask adhesive, a film adhesive, and an inner wall coating agent used for a pellicle. Or, as a substance generated by a certain source, it may be a saturated or unsaturated aliphatic hydrocarbon compound or aromatic hydrocarbon compound and these compounds may have a functional group such as ketone, ester, carboxylic acid or the like in some cases. As for the saturated or unsaturated aliphatic hydrocarbon type compound, there can be exemplified, for example, nonane, decane, undecane, 1-pentene, 2-methyloctane, 4-methyloctane, undecene, cyclooctane, dodecene, 2-methyl-1-undecene, dodecane, tetradecane, pentadecane, octadecane and the like. As for the ketone type compound, there can be exemplified, for example, acetone, methylethyl ketone, cyclohexanone, 2-methyl-3-heptanone, 2-heptanone and the like. As for the ester type compound, there can be exemplified, for example, ethyl acetate, butyl acetate, n-butyl acetate, methyl methacrylate and the like. As for the alcohols, there can be exemplified, for example, isopropanol, butanol, 2-ethylhexanol, propylene glycol monomethyl ether and the like. As for the aromatic type compound, there can be exemplified, for example, toluene, m-xylene, p-xylene, benzoic acid, cumene and the like.

[Removal of a Volatile Organic Compound Component]

In the present invention, in order to reduce the concentration of a volatile organic compound component generated from a pellicle, a pellicle or a material of the pellicle is heated under a gas flow and/or is placed under a reduced pressure environment.

In the present invention, examples of a gas used under a gas flow include, though not particularly restricted to, nitrogen, air, helium, argon and the like.

In the present invention, a gas flow rate is, though not particularly restricted to, preferably from 1 ml/min to 1,000 ml/min. When the gas flow is too lowered, it takes too long for removing a volatile organic compound component, whereas when the gas flow is too much, foreign matter is attached to a pellicle.

A method of heating is not particularly restricted as far as the method is a means which is converted into a thermal energy, including a method of irradiating a pellicle or each material of a pellicle with a light, a method of directly applying a temperature, a method of applying a vibration such as an ultrasonic wave, a method of applying pressure and the like. Among these, a method of irradiating with a light or a method of directly applying a temperature can be preferably used. In this manner, the concentration of a volatile organic compound component contained in a pellicle can be reduced.

Herein, an inside wall coating agent or a photo-mask adhesive for coating the bottom of the frame itself is considered a source for generating a volatile substance so that a treatment for removing foreign matter needs to be conducted. In this case, heating a material up to its decomposition temperature and less is effective in removing foreign matter. Usually, the material is preferably heated from 100 to 200° C. and more preferably from 140 to 180° C. Also, a treatment under a nitrogen flow not only prevents oxidation of the material, but also is effective in removing the volatile substance. Further, to remove the volatile organic compound by decompressing is preferable in viewpoints of reduced treatment temperature and reduced treatment time. The removal is usually conducted in the range of 0.001 to 55,000 Pa, preferably not more than 45,000 Pa and more preferably not more than 35,000 Pa. Further, when an inner wall coating agent or a photo-mask adhesive comprises a plurality of substances, the inner wall coating agent or the photo-mask adhesive may be manufactured after a component comprising a volatile organic compound is heated and decompressed for removing the volatile organic compound, or the volatile organic compound may be removed after the photo-mask adhesive is manufactured.

In order to remove the volatile organic compound from the completed pellicle, such removal needs to be conducted at a temperature not affecting the quality of the completed pellicle. As a result, the heating temperature is restricted. Usually, the volatile organic compound is heated at a temperature of from 40 to 100° C. for treatment. When the temperature rises too high, a pellicle film is deformed, thus causing failure in the formation of the circuit pattern, or an inner wall coating agent or a photo-mask adhesive is deformed and it cannot be completely adhered to the photo-mask at the time of its adhesion to the photo-mask, thus causing trouble in the dust-proof function in some cases. In this case, as it is not able to rise to the temperature that is heated when the volatile organic substance is removed from each component of the pellicle, the heating time needs to be adjusted.

In the present invention, the temperature for heating each member of the pellicle is preferably from 40 to 200° C. and more preferably from 40 to 180° C. Further, the temperature for heating in a state of being a pellicle is preferably from 40 to 100° C.

A reduced pressure environment in the present invention is created by using a known vacuum pump. By placing the pellicle or each material of the pellicle under a reduced pressure environment, the concentration of the volatile organic compound component can be reduced.

In the present invention, as a method of reducing the concentration of the volatile organic compound component contained in a material of the pellicle (a photo-mask adhesive, a film adhesive, and an inner wall coating agent) other than those described above, reprecipitation and refining are also effective.

In the present invention, the concentration of the volatile organic compound component is measured by a gas chromatography (GC) method. For example, to measure a gas generated from a pellicle with a small amount of gas generation or a member constituting the pellicle, the pellicle is put into a glass vessel and kept in a constant temperature. By flowing a gas for a certain period of time into the vessel, the gas flowing out of the vessel is gathered in a collecting tube for quantitatively analyzing the amount of a substance by the GC method.

Furthermore, each material of the pellicle can be analyzed by the thermal desorption cold trap injector (TCT-GC) method. This is a method comprising feeding each material of the pellicle having a certain weight into a device with a heating means and injecting a gas generated by heating directly into a GC analyzer for analyzing.

### EXAMPLES

The present invention is now illustrated below with reference to Examples.

(Method of Collecting a Gas)

A volatile substance generated from a pellicle, a member of the pellicle or the like can be collected by using a collecting material for analysis. For collecting, an adsorbent (weak polar porous polymer beads based on 2,6-diphenyl-p-phenylene oxide) was used. The properties of such an adsorbent in use are described below.

Properties of the Adsorbent

| | | |
|---|---|---|
| Specific surface area: | 35 | m²/g |
| Pore volume: | 2.4 | cm²/g |
| Average pore size: | 200 | nm |
| Density: | 0.25 | g/cm³ |

A commercially available product (trade name: TENAX-GR or TENAX-TA, manufactured by GL Sciences Inc.) can be used for this adsorbent. In Examples below, an organic compound component generated from a pellicle passed through a collecting tube (a collecting tube for JHS-100) charged with 3 ml of the adsorbent while flowing a nitrogen flow of 100 ml/min to form a sample.

The sample was introduced into a GC apparatus using a head space sampler (JHS-100A (a product of Japan Analytical Industry Co., Ltd.)) and the collecting tube was heated at 260° C. for 15 minutes for thermal desorption. The thus-generated gas was analyzed according to the GC/MS method. Analytic conditions for the GC/MS method were described in Table 1.

TABLE 1
GC/MS Analytical Conditions

| | |
|---|---|
| Apparatus | JMS SX102A, a product of JEOL Ltd. |
| Data processing | MS-MP7000, a product of JEOL Ltd. |
| GC | HP5890 |
| Carrier gas | Helium 15 ml/min |
| Column | CP-sil-5CB 30 m × 0.25 mmID |
| Column temperature | 40 to 280° C., rate of rising temperature |
| | 6° C./min |
| Ionization method | EI |
| Ionization energy | 70 eV |
| Ionization current | 300 μA |
| Ion accelerating voltage | 6 KV |
| Ion source temperature | 200° C. |
| Multi-step electronic | 1.00 KV |
| multiplier tube voltage | |
| Scanning rate | 0.5 sec/scan |
| Scanning interval | 0.7 sec |

### Example 1

An oven in use had a cleanliness of 100 in order to prevent foreign matter from attaching to a pellicle. A completed product (17.1341 g) of a pellicle was allowed to stand in the oven set to 50° C. for 24 hours under an atmospheric pressure in a state that a liner was taken off in order to best remove a volatile organic compound from a photo-mask adhesive. Then, the pellicle was put into a glass chamber (24 cm×24 cm×8 cm) and while a nitrogen gas was flown thereinto at a rate of 100 ml/min from a gas cylinder, the generated gas passed through a collecting tube charged with about 3 ml of an adsorbent (TENAX-GR), and the organic substance was concentrated with the adsorbent for sampling. This sampling was conducted at a room temperature of 26° C. for 24 hours. A substance sampled from the collecting tube was heated at 260° C. for 15 minutes for thermal desorption and the generated gas was analyzed by GC/MS. The analytic results were shown in a table. The numerical figures shown in the table were calculated such that the weight of each compound obtained by the absolute calibration method (toluene used as a reference substance) was divided by the weight per pellicle. The results are shown in Table 2.

As a result of heating the pellicle, as apparent from the analytic results (refer to Comparative Example 1 to be described below), all of the detected compounds were decreased and decreased to about ⅕ in total as compared to those before the treatment. From this fact, a substance generated from the pellicle by heating was found to be decreased.

Then, the heated pellicle was attached to the photo-mask and allowed to stand at the 50° oven for 3 hours to form a sample for the confirmation of foreign matter. Then, both samples were irradiated with an ArF excimer laser beam. The irradiation conditions are an oscillating frequency of 500 Hz, an energy density of 1 mJ/cm²/pulse and an irradiation up to 2,000 J/cm². As a result, foreign-matter deposits were not found on the photo-mask to which the heated pellicle was attached and on the pellicle film. The results are shown in Table 3.

### Comparative Example 1

A treatment was carried out in the same manner as in Example, except that the treatment was conducted in an oven for 12 hours. The gas generation amount of a pellicle obtained by the treatment is shown in Table 2.

When the thus-obtained pellicle was attached to a photo-mask and irradiated with an ArF excimer laser beam in the same manner as in Example 1, the color of a laser beam irradiated area of the pellicle film turned into white. Thus, foreign-matter deposits having a diameter of about 0.2 micrometers were confirmed on the photo-mask. The results are shown in Table 3.

### Example 2

A photo-mask adhesive for attaching a pellicle frame to a photo-mask was heated up to 200° C. and heat-treated under a reduced pressure environment of 35,000 Pa for 4 hours so that a substance generated from the photo-mask adhesive was reduced in advance. The amount of the substance generated from the photo-mask adhesive was measured by the TCT-GC method. 20 mg of the photo-mask adhesive was heated at 100° C. for 3 minutes. Then, the amount of a gas generated therefrom was measured. As a result, the amount of the generated gas was reduced to about ⅛ as compared to an untreated photo-mask adhesive.

Next, an inner wall coating agent was dissolved in acetone to have 20 weight % and put into an egg plant type flask. Then, the resulting solution was allowed to stand at 5,000 Pa and 120° C. for 6 hours so that a substance generated from the inner wall coating agent was reduced in advance. The amount of the substance generated from the inner wall coating agent was measured by the TCT-GC method. 20 mg of the inner wall coating agent was heated at 100° C. for 3 minutes. Then, the amount of a gas generated therefrom was measured. As a result, the amount of the generated gas was reduced to about ⅕ as compared to an untreated inner wall coating agent.

A pellicle was manufactured by using the photo-mask adhesive and inner wall coating agent. Further, the pellicle was attached to the photo-mask and allowed to stand at a 50° C. oven for 3 hours to form a sample for the confirmation of foreign matter in the same manner as in Example 1. This sample was irradiated with an ArF laser in the same manner as in Example 1. As a result of observation after an irradiation with 100, 1,000, 2,000, 5,000, 10,000 and 20,000 J/cm², foreign matter was not found on the pellicle film and the photo-mask in any case.

### Comparative Example 2

A pellicle was manufactured by using an untreated photo-mask adhesive. Further, the pellicle was attached to the photo-mask and allowed to stand at a 50° C. oven for 3 hours to form a sample for the confirmation of foreign matter in the same manner as in Example 1. This sample was irradiated with an ArF laser in the same manner as in Example 1. As a result of observation after an irradiation with 100 J/cm², foreign matters ware found on a pellicle film and the photo-mask, and between the pellicle film and the photo-mask. As a result of confirmation with a foreign matter detector, 2305 foreign matters were confirmed.

### Comparative Example 3

A pellicle was left to stand at a room temperature of about 25° C. for an extended period of time (about a year). The results in this case are shown in a table.

Consequently, C₅H₁₀, methyl acrylate and butanol are reduced to 0.01 ppm and less respectively. However, the amount of other volatile organic compound components was not changed for the most part.

TABLE 2
Analytic Results of Volatile Organic Compound Component from
Pellicle (unit: ppm)

| Compound | | Comparative | Comparative | Comparative |
|---|---|---|---|---|
| Name | Example 1 | Example 1 | Example 2 | Example 3 |
| C₅H₁₀ | 0.01 | 0.01 | 0.06 | 0.01 and less |
| Methyl acrylate | 0.04 | 0.12 | 0.22 | 0.01 and less |
| Butanol | 0.01 and less | 0.01 | 0.02 | 0.01 and less |
| C₈H₁₆ | 0.02 | 0.05 | 0.13 | 0.11 |
| C₉H₂₀ | 0.02 | 0.05 | 0.09 | 0.08 |
| C₉H₂₀ | 0.01 and less | 0.01 | 0.01 and less | 0.01 and less |
| C₉H₂₀ | 0.01 and less | 0.01 | 0.02 | 0.02 |
| C₃ alkyl | 0.01 and less | 0.01 | 0.01 | 0.01 |
| benzene | | | | |
| C₁₀H₂₂ | 0.01 and less | 0.01 and less | 0.01 | 0.01 |
| C₁₁H₂₄ | 0.01 and less | 0.01 and less | 0.01 | 0.01 |
| C₁₁H₂₄ | 0.01 and less | 0.01 and less | 0.01 | 0.01 |
| C₁₁H₂₄ | 0.01 and less | 0.02 | 0.04 | 0.04 |
| C₁₁H₂₂ | 0.01 and less | 0.02 | 0.02 | 0.02 |
| Methyl | 0.01 and less | 0.01 | 0.02 | 0.02 |
| benzoic acid | | | | |
| C₁₂H₂₆ | 0.01 | 0.04 | 0.08 | 0.06 |
| C₁₂H₂₆ | 0.01 and less | 0.01 | 0.02 | 0.02 |
| C₁₅H₃₂ | 0.01 and less | 0.01 | 0.03 | 0.03 |
| C₁₇H₃₆ | 0.01 and less | 0.01 and less | 0.01 | 0.02 |
| C₁₈H₃₈ | 0.01 | 0.01 | 0.04 | 0.03 |
| C₂₁H₄₄ | 0.01 and less | 0.02 | 0.02 | 0.02 |
| MW 128 | 0.01 and less | 0.05 | 0.08 | 0.09 |
| aliphatic cyclic | | | | |
| compound | | | | |
| Unknown | 0.004 | 0.01 | 0.02 | 0.02 |
| component | | | | |
| Unknown | 0.01 | 0.03 | 0.02 | 0.02 |
| component | | | | |
| Unknown | 0.01 | 0.02 | 0.04 | 0.03 |
| component | | | | |
| Total | 0.29 and less | 0.56 and less | 1.03 and less | 0.71 |

TABLE 3
Confirmation Results of Foreign Matter

| | Comparative | Comparative |
|---|---|---|
| Example 1 | Example 1 | Example 2 |
| Nothing | Nothing | Many foreign matters of about |
| | | 2 μm found |

### INDUSTRIAL APPLICABILITY

When the pellicle of the present invention is used, it is possible to prevent the formation of foreign-matter deposits on a photo-mask during laser beam irradiation and storage, and keep a high pattern accuracy for an extended period of time even when an exposure is made using a KrF or ArF excimer laser beam. Thus, the pellicle has an important meaning in industry and in use.

What is claimed is:

1. A pellicle, wherein a total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under the nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed.

2. A method of manufacturing a pellicle, wherein a total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under the nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed,
wherein an act of removing the volatile organic compound from the pellicle is carried out.

3. The method of manufacturing the pellicle according to claim 2, wherein an act of removing the volatile organic compound from a member used for manufacturing the pellicle is carried out.

4. A pellicle-fed photo-mask with a pellicle being mounted thereon, wherein a total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under the nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed.

5. A method of manufacturing a semiconductor device using a photo-mask in a state that a pellicle is mounted thereon, wherein a total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under the nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed.

6. A method of using a pellicle, wherein a total weight of a volatile organic compound to be detected is not more than 0.5 ppm based on the pellicle weight when an organic compound component generated from the pellicle is collected at a room temperature of 26° C. for 24 hours under a nitrogen flow of 100 ml/min, the organic compound component collected under the nitrogen flow is adsorbed by a porous polymer beads adsorbent based on 2,6-diphenyl-p-phenylene oxide, the adsorbed organic compound component is heated at 260° C. for 15 minutes so that the organic compound component is thermally desorpted from the adsorbent in a gas form, and the thus-generated gas is analyzed,
wherein the pellicle is used for preventing dust in a process of manufacturing a semiconductor device.
